(19) United States
(12) Patent Application Publication
(10) Pub. No.: US 2021/0224668 A1
(43) Pub. Date: Jul. 22, 2021

(54) SEMICONDUCTOR DEVICE FOR COMPRESSING A NEURAL NETWORK BASED ON A TARGET PERFORMANCE, AND METHOD OF COMPRESSING THE NEURAL NETWORK

(71) Applicants: SK Hynix Inc, Icheon (KR); Korea Advanced Institute of Science and Technology, Daejeon (KR)

(72) Inventors: Hyeji KIM, Bucheon (KR); Chong-Min KYUNG, Daejeon (KR)

(21) Appl. No.: 17/090,609

(22) Filed: Nov. 5, 2020

(30) Foreign Application Priority Data
Jan. 16, 2020 (KR) 10-2020-0006136

(51) Int. Cl. G06N 5/04; G06N 3/04; H03M 7/30

(52) U.S. Cl. CPC G06N 5/04; H03M 7/70; G06N 3/04

(57) ABSTRACT

A semiconductor device includes a compression circuit configured to generate a compressed neural network by compressing a neural network according to each of a plurality of compression ratios; a performance measurement circuit configured to measure performance of the compressed neural network from an inference operation that is performed by an inference device on the compressed neural network; and a relation calculation circuit configured to calculate a relation function between the plurality of compression ratios and performance corresponding to the plurality of compression ratios, determine a target compression ratio referring to the relation function when target performance is determined, and provide the target compression ratio to the compression circuit, wherein the compression circuit compresses the neural network according to the target compression ratio.

### CROSS-REFERENCE TO RELATED APPLICATION

The present application claims priority under 35 U.S.C. § 119(a) to Korean Patent Application No. 10-2020-0006136, filed on Jan. 16, 2020, which is incorporated herein by reference in its entirety.

### BACKGROUND

### 1. Technical Field

Various embodiments generally relate to a semiconductor device that compresses a neural network, and a method of compressing the neural network.

### 2. Related Art

Recognition technology based on neural networks shows relatively high recognition performance.

However, it is not suitable to use it in a mobile device that does not have enough resources due to excessive memory usage and processor computation.

For example, when resources are insufficient in a device, there is a limitation on performing parallel processing operations for neural network processing, and thus, a computation time of the device increases significantly.

In the case of compressing a neural network including a plurality of layers, compression is performed for each of the plurality of layers in the related art. Accordingly, there is a problem that a compression time excessively increases.

Conventionally, since compression is performed based on a theoretical index such as Floating Point Operations Per Second (FLOPS), it is difficult to know whether a target performance can be achieved after neural network compression.

### SUMMARY

In accordance with an embodiment of the present disclosure, a semiconductor device includes a compression circuit configured to generate a compressed neural network by compressing a neural network according to each of a plurality of compression ratios; a performance measurement circuit configured to measure performance of the compressed neural network from an inference operation that is performed by an inference device on the compressed neural network; and a relation calculation circuit configured to calculate a relation function between the plurality of compression ratios and performance corresponding to the plurality of compression ratios, determine a target compression ratio referring to the relation function when target performance is determined, and provide the target compression ratio to the compression circuit, wherein the compression circuit compresses the neural network according to the target compression ratio.

In accordance with an embodiment of the present disclosure, a method of compressing a neural network may include compressing the neural network according to each of a plurality of compression ratios to output a compressed neural network; measuring a latency corresponding to said each of the plurality of compression ratios based on an inference operation that is performed on the compressed neural network; calculating a relation function between the plurality of compression ratios and a plurality of latencies respectively corresponding to the plurality of compression ratios; determining a target compression ratio corresponding to a target latency using the relation function; and compressing the neural network according to the target compression ratio.

### BRIEF DESCRIPTION OF THE DRAWINGS

The accompanying figures, where like reference numerals refer to identical or functionally similar elements throughout the separate views, together with the detailed description below, are incorporated in and form part of the specification, and serve to further illustrate various embodiments, and explain various principles and advantages of those embodiments.

FIG. 1 illustrates a semiconductor device according to an embodiment of the present disclosure.

FIG. 2 is a flowchart illustrating an operation of a compression circuit according to an embodiment of the present disclosure.

FIG. 3 illustrates a relation table according to an embodiment of the present disclosure.

FIG. 4 is a graph illustrating an operation of a relation calculation circuit according to an embodiment of the present disclosure.

FIG. 5 is a flowchart illustrating an operation of a semiconductor device according to an embodiment of the present disclosure.

### DETAILED DESCRIPTION

The following detailed description references the accompanying figures in describing illustrative embodiments consistent with this disclosure. The embodiments are provided for illustrative purposes and are not exhaustive. Additional embodiments not explicitly illustrated or described are possible. Further, modifications can be made to presented embodiments within the scope of the present teachings. The detailed description is not meant to limit this disclosure. Rather, the scope of the present disclosure is defined in accordance with claims and equivalents thereof. Also, throughout the specification, reference to “an embodiment” or the like is not necessarily to only one embodiment, and different references to any such phrase are not necessarily to the same embodiment(s).

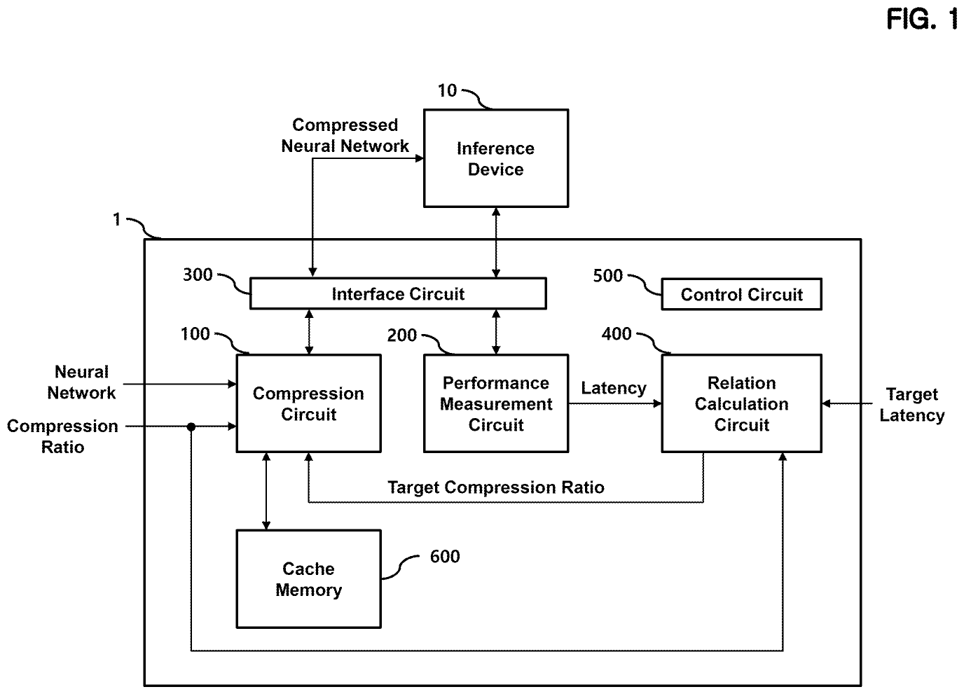

FIG. 1 illustrates a semiconductor device 1 according to an embodiment of the present disclosure.

Referring to FIG. 1, the semiconductor device 1 includes a compression circuit 100, a performance measurement circuit 200, an interface circuit 300, a relation calculation circuit 400, and a control circuit 500.

The compression circuit 100 receives a neural network and a compression ratio, compresses the neural network according to the compression ratio, and outputs a compressed neural network.

The neural network input to the semiconductor device 1 is a neural network that has been trained. In this embodiment, any neural network compression method can be used to compress the neural network.

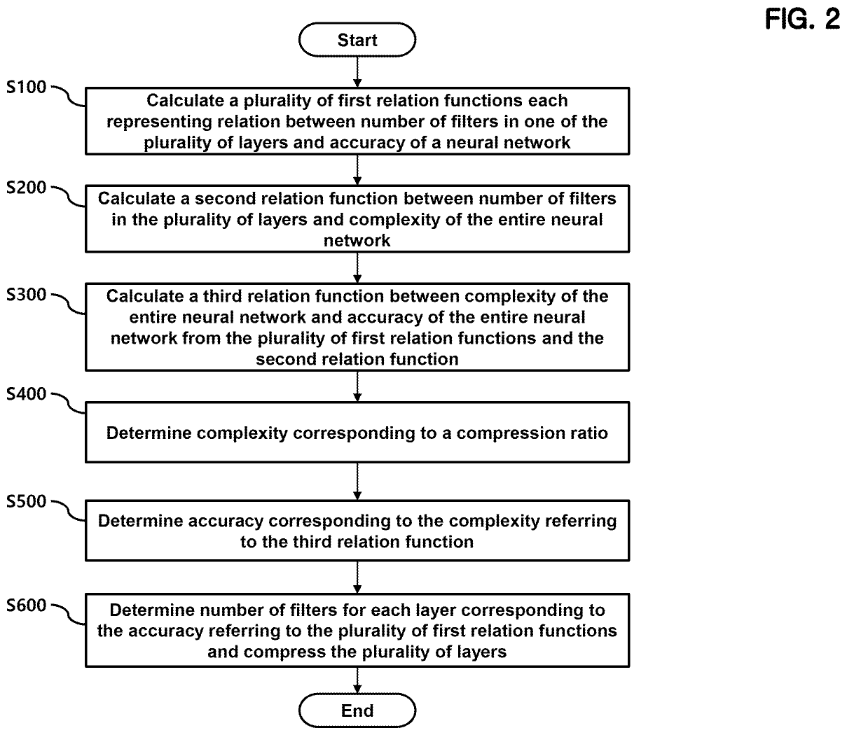

FIG. 2 is a flowchart illustrating an operation of the compression circuit 100 of FIG. 1 according to an embodiment.

In FIG. 2, it is assumed that a neural network input to the compression circuit 100 is a convolutional neural network (CNN) including a plurality of layers.

First, each of the plurality of layers included in the neural network has a plurality of convolution filters, and each of the plurality of layers filters input data and transmits filtered input data to the next layer.

Hereinafter, a convolution filter may be referred to as a ‘filter.’

In this embodiment, a neural network operation is performed to calculate accuracy of the neural network by sequentially removing filters having lower importance from one layer of a plurality of layers while maintaining filters of each of the remaining layers except the one layer.

Since it is well known to arrange a plurality of filters included in one layer in order of importance, detailed description thereof is omitted.

Accordingly, referring to FIG. 2, a plurality of first relation functions each representing relation between the number of filters used in a corresponding one of the plurality of layers and accuracy of the neural network according to the number of filters used in the corresponding layer are derived at step S100.

To calculate the first relation function, a conventional numerical analysis and statistical technique can be applied. Therefore, a detailed description of the calculation of the first relation function is omitted.

Thereafter, a second relation function between the number of filters used in the plurality of layers and complexity of the entire neural network is calculated at step S200. The entire neural network may be used to be distinguished from each of the plurality of layers in the neural network.

A method of calculating the complexity of the entire neural network is well known. In this embodiment, the complexity of the entire neural network is determined by a linear combination of the numbers of filters used for the plurality of layers.

Thereafter, a third relation function between complexity of the entire neural network and accuracy of the entire neural network is calculated by considering a case in which the plurality of first relation functions of the plurality of layers have the same accuracy, with reference to the plurality of first relation functions and the second relation function at step S300.

To calculate the third relational function, a conventional numerical analysis and statistical technique can be applied, so a detailed description of the calculation is omitted.

The above steps S100 to S300 may be performed in advance when the neural network is determined.

Thereafter, when a target compression ratio is input, target complexity of the neural network that corresponds to the target compression ratio is determined at step S400.

Since a compression ratio can be determined from a ratio of first complexity after compression is performed to second complexity when the compression is not performed, target complexity of the neural network corresponding to a target compression ratio can be determined from the target compression ratio.

Thereafter, target accuracy corresponding to the target complexity is determined with reference to the third relation function at step S500.

Thereafter, the number of filters for each layer that corresponds to the target accuracy is determined by referring to the plurality of first relation functions corresponding to the target accuracy at step S600.

In the present embodiment, when the number of filters for each layer is determined, the compression is performed on each layer by removing filters of lower importance from each layer.

As described above, given the neural network, the first to third relation functions may be determined in advance.

Therefore, when the target compression ratio of the entire neural network is provided, determining the number of filters for each layer corresponding to the target compression ratio and performing the compression accordingly may be performed at a high speed.

Returning to FIG. 1, when the compression circuit 100 performs the compression on the neural network, the interface circuit 300 receives the compressed neural network from the compression circuit 100 and provides it to the inference device 10.

The inference device 10 may be any device that performs an inference operation using the compressed neural network.

For example, when face recognition is performed by a neural network installed on a smartphone, the smartphone corresponds to the inference device 10.

The inference device 10 may be a smartphone or a semiconductor chip specialized to perform an inference operation.

The inference device 10 may be a separate device from the semiconductor device 1 or may be included in the semiconductor device 1.

The performance measurement circuit 200 may measure performance when the inference device 10 performs the inference operation using the compressed neural network.

In this embodiment, the performance measurement circuit 200 measures the performance by measuring a latency corresponding to an interval between an input time when an input signal, e.g., the compressed neural network, is provided to the inference device 10 and an output time when an output signal of the inference operation is output from the inference device 10. The performance measurement circuit 200 may receive information corresponding to the input time and the output time from the inference device 10 through the interface circuit 300.

The relation calculation circuit 400 calculates relation between the compression ratio provided to the compression circuit 100 and the performance measured by the performance measurement circuit 200.

The compression circuit 100 receives a plurality of compression ratios and generates a plurality of compressed neural networks respectively corresponding to the plurality of compression ratios in sequence or in parallel.

The plurality of compressed neural networks are provided to the inference device 10 in sequence or in parallel through the interface circuit 300.

The performance measurement circuit 200 measures a plurality of latencies for the plurality of compressed neural networks respectively corresponding to the plurality of compression ratios.

The relation calculation circuit 400 calculates a relation function between a compression ratio and a latency by using information representing relation between each of the plurality of compression ratios and a corresponding one of the plurality of latencies.

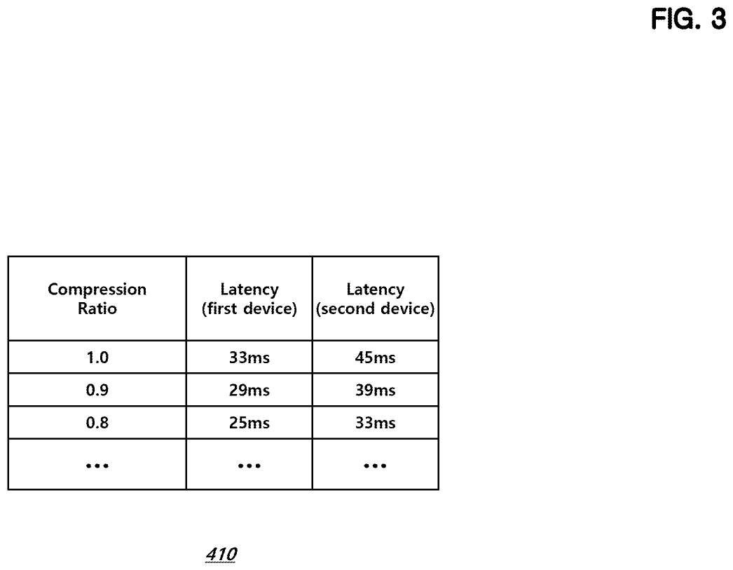

FIG. 3 is a relation table 410 representing relation between a compression ratio and a latency.

In the present embodiment, it is assumed that the relation table 410 is included in the relation calculation circuit 400 of FIG. 1, but location of the relation table 410 may be variously changed according to embodiments.

The relation table 410 includes a compression ratio field and a latency field.

A plurality of latency fields may be included in the relation table 410 when there is a plurality of inference devices 10.

In this embodiment, two latency fields corresponding to a first device and a second device are included in the relation table 410. The first and second devices correspond to the plurality of inference devices 10.

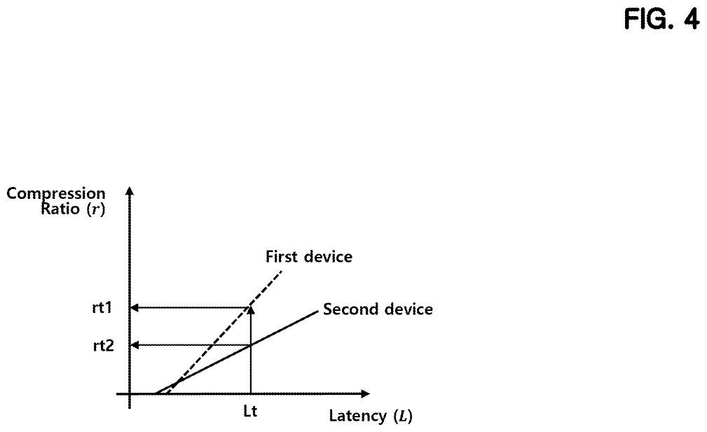

For each of the first and second devices, the relation calculation circuit 400 calculates a relation function between a compression ratio and a latency by referring to the relation table 410, as illustrated in FIG. 4.

Since the relation calculation circuit 400 can apply well-known numerical analysis and statistical techniques to calculate the relation function, a detailed description of the calculation of the relation function is omitted.

Returning to FIG. 1, the relation calculation circuit 400 determines a target compression ratio corresponding to a target latency provided thereto after determining the relation function.

FIG. 4 is a graph illustrating an operation of determining target compression ratios rt1 and rt2 corresponding to a target latency Lt by using a relation function between a latency and a compression ratio calculated by the relation calculation circuit 400.

For example, for the first device, the target compression ratio rt1 may be determined in correspondence with the target latency Lt, and for the second device, the target compression ratio rt2 may be determined in correspondence with the target latency Lt.

When a target compression ratio for the inference device 10 is determined by the relation calculation circuit 400, the relation calculation circuit 400 provides the target compression ratio to the compression circuit 100 and the compression circuit 100 compresses the neural network according to the target compression ratio and outputs the compressed neural network to the inference device 10 through the interface circuit 300.

That is, when a neural network that has been trained is input thereto, the compression circuit 100 compresses the neural network according to each of a plurality of compression ratios and sends a compressed neural network to the inference device 10 through the interface circuit 300. The inference device 10 performs an inference operation using the compressed neural network, and the performance measurement circuit 200 measures a performance, i.e., a latency, of the inference operation for each of the plurality of compression ratios. For each of the plurality of compression ratios, the relation calculation circuit 400 includes a latency and a corresponding compression ratio in the relation table 410, and calculates a relation function between a compression ratio and a latency by referring to the relation table 410. After that, when a target latency is input thereto, the relation calculation circuit 400 determines a target compression ratio corresponding to the target latency based on the relation function, and provides the target compression ratio to the compression circuit 100. The compression circuit compresses the neural network using the target compression ratio.

The semiconductor device 1 may further include a cache memory 600.

The cache memory 600 stores one or more compressed neural networks each corresponding to a corresponding compression ratio.

When a compression ratio or a target compression ratio is provided, the compression circuit 100 may check whether a corresponding compressed neural network is stored in the cache memory 600, and when the corresponding compressed neural network is stored in the cache memory 600, the corresponding compressed neural network may be provided to the compression circuit 100.

The control circuit 500 controls the overall operation of the semiconductor device 1 to generate a compressed neural network corresponding to a target performance.

In an embodiment, the compression circuit 100, the performance measurement circuit 200, and the relation calculation circuit 400 shown in FIG. 1 may be implemented with software, hardware, or both. For examples, the above components 100, 200, and 400 may be implemented using one or more processors.

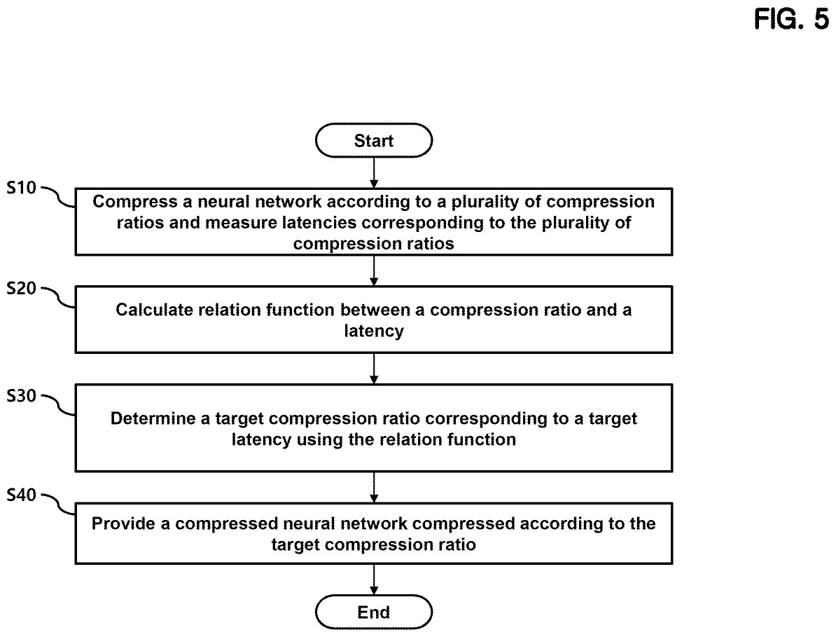

FIG. 5 is a flowchart showing an operation of the semiconductor device 1 according to an embodiment. The operation illustrated in FIG. 5 will be described with reference to FIG. 1.

For example, the operation illustrated in FIG. 5 may be performed under the control of the control circuit 500.

First, at step S10, the compression circuit 100 compresses a neural network according to a plurality of compression ratios, and the performance measurement circuit 200 measures a plurality of latencies respectively corresponding to the plurality of compression ratios.

The relation calculation circuit 400 calculates a relation function between the plurality of compression ratios and the plurality of latencies at step S20.

After that, the relation calculation circuit 400 determines a target compression ratio corresponding to a target latency using the relation function at step S30.

After the target compression ratio is determined, the compression circuit 100 compresses the neural network according to the target compression ratio to provide a compressed neural network at step S40.

Although various embodiments have been illustrated and described, various changes and modifications may be made to the described embodiments without departing from the spirit and scope of the invention as defined by the following claims.

What is claimed is:

1. A semiconductor device comprising:
a compression circuit configured to generate a compressed neural network by compressing a neural network according to each of a plurality of compression ratios;
a performance measurement circuit configured to measure performance of the compressed neural network from an inference operation that is performed by an inference device on the compressed neural network; and
a relation calculation circuit configured to calculate a relation function between the plurality of compression ratios and performance corresponding to the plurality of compression ratios, determine a target compression ratio referring to the relation function when target performance is determined, and provide the target compression ratio to the compression circuit,
wherein the compression circuit compresses the neural network according to the target compression ratio.

2. The semiconductor device of claim 1, further comprising an interface circuit configured to provide the compressed neural network to the inference device.

3. The semiconductor device of claim 1, wherein the performance measurement circuit measures the performance by measuring a latency that corresponds to an interval between an input time when the compressed neural network is provided to the inference device and an output time when an output signal of the inference operation is output from the inference device.

4. The semiconductor device of claim 1, further including a relation table storing relation between each of the plurality of compression ratios and the performance corresponding to each of the plurality of compression ratios.

5. The semiconductor device of claim 1, further comprising a control circuit for controlling the compression circuit, the performance measurement circuit, and the relation calculation circuit to compress the neural network to achieve the target performance.

6. The semiconductor device of claim 1, further comprising a cache memory to store one or more compressed neural networks corresponding to the plurality of compression ratios.

7. The semiconductor device of claim 1, wherein the neural network includes a plurality of layers each including a plurality of filters performing computation.

8. The semiconductor device of claim 7, wherein the compression circuit determines a number of filters included in each of the plurality of layers according to a compression ratio.

9. The semiconductor device of claim 8, wherein the compression circuit determines a plurality of first relation functions each representing relation between a number of filters included in a corresponding layer and accuracy of the neural network according to the number of filters used in the corresponding layer.

10. The semiconductor device of claim 9, wherein the compression circuit determines a second relation function representing relation between a number of filters included in the plurality of layers and complexity of the neural network.

11. The semiconductor device of claim 10, wherein the compression circuit determines a third relation function representing relation between accuracy and complexity by referring to the plurality of first relation functions and the second relation function.

12. The semiconductor device of claim 11, wherein the compression circuit determines target complexity corresponding to the target compression ratio, determines target accuracy corresponding to the target complexity, and determines a number of filters included in each of the plurality of layers by referring to a plurality of first relation functions corresponding to the target accuracy.

13. A method of compressing a neural network, comprising:
compressing the neural network according to each of a plurality of compression ratios to output a compressed neural network;
measuring a latency corresponding to said each of the plurality of compression ratios based on an inference operation that is performed on the compressed neural network;
calculating a relation function between the plurality of compression ratios and a plurality of latencies respectively corresponding to the plurality of compression ratios;
determining a target compression ratio corresponding to a target latency using the relation function; and
compressing the neural network according to the target compression ratio.

14. The method of claim 13, further comprising:
including the plurality of compression ratios and the plurality of latencies in a relation table,
wherein the relation function is calculated based on the relation table.

15. The method of claim 13, further comprising:
storing the compressed neural network corresponding to said each of the plurality of compression ratios in a cache memory; and
providing a compressed neural network corresponding to the target compression ratio that is stored in the cache memory in response to the target compression ratio.

16. The method of claim 13, wherein the inference operation is performed by an inference device.

17. The method of claim 13, wherein measuring the latency comprises:
measuring an interval between an input time when the compressed neural network is provided to an inference device and an output time when an output signal of the inference operation is output from the inference device.

18. The method of claim 13, wherein the neural network includes a plurality of layers each including a plurality of filters, compressing the neural network according to each of the plurality of compression ratios comprises:
determining a number of filters included in each of the plurality of layers according to a compression ratio;
determining a plurality of first relation functions each representing relation between a number of filters included in a corresponding layer and accuracy according to the number of filters used in the corresponding layer;
determining a second relation function representing relation between a number of filters included in the plurality of layers and complexity of the neural network; and
determining a third relation function representing relation between accuracy of the neural network and the complexity by referring to the plurality of first relation functions and the second relation function.

19. The method of claim 18, wherein compressing the neural network according to the target compression ratio comprises:
determining target complexity corresponding to the target compression ratio;
determining target accuracy corresponding to the target complexity;
determining a number of filters included in each of the plurality of layers by referring to a plurality of first relation functions corresponding to the target accuracy; and
compressing each of the plurality of layers based on the determined number of filters.
